(19) United States
(12) Patent Application Publication
(10) Pub. No.: US 2002/0093084 A1
(43) Pub. Date: Jul. 18, 2002

(54) Semiconductor device protecting a semiconductor chip mounted over a substrate with a molding formed by an injection molding method

(76) Inventors: Masato Horiike, Yokohama-shi (JP); Kazunori Kanebako, Yokohama-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 09/805,038

(22) Filed: Mar. 14, 2001

(30) Foreign Application Priority Data
Jan. 16, 2001 (JP) 2001-007990

(51) Int. Cl. H01L 23/02

(52) U.S. Cl. 257/679

(57) ABSTRACT

A plurality of projections each are arranged on a substrate at an interval smaller than a predetermined distance and made of an insulating material. A semiconductor chip is arranged over a substrate on which these projections are formed. A mounting material is provided between the substrate and the semiconductor chip to achieve a bond therebetween.

### CROSS-REFERENCE TO RELATED APPLICATIONS

This application is based upon and claims the benefit of priority from the prior Japanese Patent Application No. 2001-007990, filed Jan. 16, 2001, the entire contents of which are incorporated herein by reference.

### BACKGROUND OF THE INVENTION

The present invention relates to a semiconductor device for protecting a semiconductor chip which is mounted over a substrate with a molding formed by an injection molding method.

In recent times, attention has been paid to smart media, that is, one kind of a semiconductor memory incorporated memory card, as a memory medium for use in a compact handheld device. In the digital camera, etc., in particular, such smart media are adopted as a medium for storing image information, etc. Since, as such media, a demand is made for a compact and thin type, an injection molding method is utilized to provide a molding for protecting a semiconductor chip mounted over a substrate.

Now an explanation will be made below about a semiconductor device, as represented by the smart media, protecting a semiconductor chip which is mounted over a substrate with a molding formed by an injection molding method.

FIG. 1A is a plan view showing a structure of the conventional semiconductor device and FIGS. 1B and 1C, each, show a structure of the semiconductor device.

As shown in FIGS. 1A and 1B, a resist material 102 is formed on a substrate 101 and a mounting paste 103 is coated on the resist material. A semiconductor chip 104 is bonded by the mounting paste 103 to the resist material 102. A respective bonding wire 105 is provided between a corresponding pad on the semiconductor chip 104 and a corresponding pad on the substrate 101.

In the manufacture of such a semiconductor device, after the resist material 102 has been formed on the substrate 101, the mounting paste 103 is coated on the resist material 102. By the mounting paste 103 the semiconductor chip 104 is bonded to the substrate 101. Here, Although the example of forming the resist material 102 on the substrate 101 and then coating the mounting paste 103 on the resist material 102 has been explained above, there is sometimes the case where a mounting paste 103 is coated on the substrate.

As this time, an amount of mounting paste 103 to be coated is determined by the performance of a mounting paste coating dispenser and its control. In the case where, for example, a greater amount of mounting paste 103 has to be coated or a greater force acts when the semiconductor chip 104 is pushed down toward the substrate 101, the mounting paste 103 is pushed out from the chip's edge and, as the case may be, reaches the semiconductor chip 104. While, on the other hand, less amount of mounting paste 103 has to be coated or less force acts when the semiconductor chip 104 is pushed down toward the substrate, the mounting paste 103 is not buried at the chip's edge and, as shown in FIG. 1C, an air cavity is created between the edge portion of the semiconductor chip 104 and the resist material 102, that is, no mounting paste 103 is present at the air cavity.

After this, respective bonding wires 105 are provided and a molding for protecting the semiconductor chip 104 and bonding wires is so formed as to cover the semiconductor chip 104 and bonding wires 105. This molding is formed by an injection molding method by injecting a molten molding material from above the semiconductor chip 101.

In the injection molding thus performed, the molten molding material is injected under a predetermined pressure from above the semiconductor chip. If, therefore, any air cavity is created beneath the semiconductor chip 104 as shown in FIG. 1C, there is sometimes the case where a crack occurs in the semiconductor chip 104.

### BRIEF SUMMARY OF THE INVENTION

It is accordingly the object of the present invention to provide a semiconductor device which can control a formed state of a mounting paste formed beneath a semiconductor chip and reduce a possible occurrence of any crack in a semiconductor chip.

In order to achieve the object of the present invention, there is provided a semiconductor device according to one aspect of the present invention, comprising a plurality of projections each formed on a substrate at an interval smaller than a predetermined distance and made of an insulating material, a semiconductor chip positioned over these projections, and a mounting material formed between the substrate and the semiconductor chip to achieve a bond therebetween.

In order to achieve the above-mentioned object of the present invention there is provided a semiconductor device according to a second aspect of the present invention, comprising a plurality of projections each arranged on a substrate at an interval smaller than a predetermined distance and made of an insulating material, a semiconductor chip arranged on these projections, and an insulating material formed between the substrate and the semiconductor chip and between projections on one hand and the semiconductor chip on the other hand to achieve a bond therebetween.

In order to achieve the above-mentioned object of the present invention there is provided a semiconductor device according to a third aspect of the present invention, comprising a plurality of projections each arranged on a substrate at on interval smaller than a predetermined distance and made of an insulating material, a semiconductor chip arranged on these projections, an insulating material formed between the substrate and the semiconductor chip and between projections on one hand and the semiconductor chip on the other hand to achieve a bond, bonding wires formed between the substrate and the semiconductor chip, and a molding formed on the semiconductor chip and bonding wires.

In the semiconductor device having such a structure, when a predetermined pressure is applied to the semiconductor chip by, for example, injecting a molten molding material from above the semiconductor chip by an injection molding method, even if an air cavity is present beneath the semiconductor chip, the above-mentioned projections serves as a support and it is, therefore, possible to suppress the deformation of the semiconductor chip and, by doing so, there is no possibility that bending stress will be applied to the semiconductor chip to an extent that a crack occurs in the semiconductor chip. As a result, it is possible to present the occurrence of any crack in the semiconductor device.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1A is a plan view showing an arrangement of a conventional semiconductor device;

FIGS. 1B and 1C are cross-sectional views showing a structure of the semiconductor device;

FIGS. 2A and 2B are cross-sectional views showing a structure of a semiconductor device according to an embodiment of the present invention; and

FIG. 2C is a top view showing an array of resist materials on a substrate of the semiconductor device.

### DETAILED DESCRIPTION OF THE INVENTION

The embodiment of the present invention will be described below with reference to the accompanying drawing.

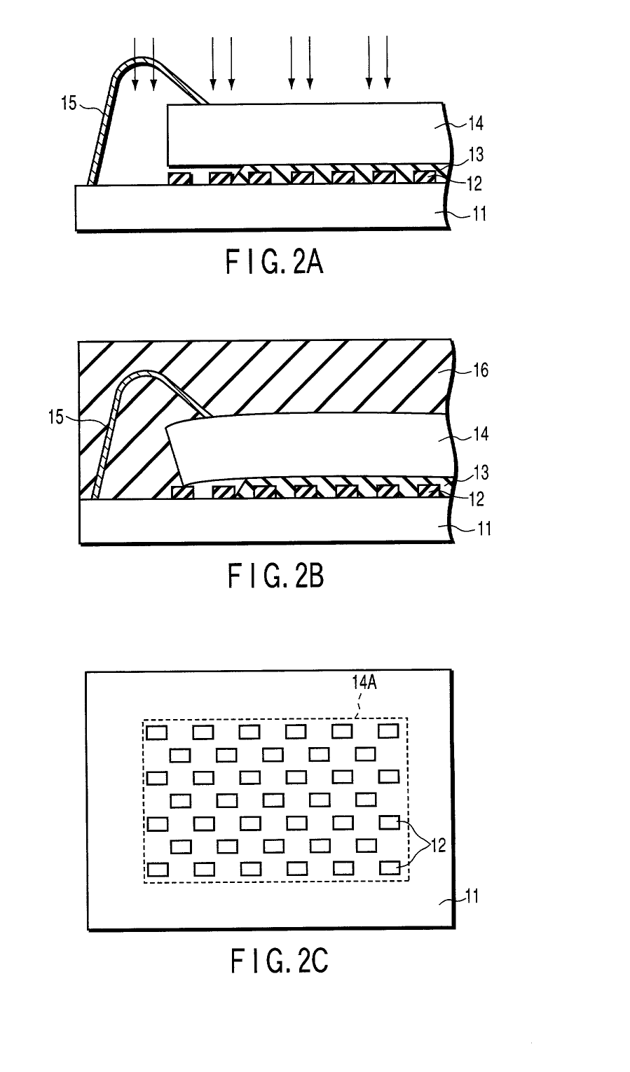

FIGS. 2A and 2B, each, are a cross-sectional view showing a structure of a semiconductor device according to an embodiment of the present invention. FIG. 2C is a top view showing an array of resist materials on a substrate of the semiconductor device. It is to be noted that FIG. 2A shows a state before forming a molding and FIG. 2B shows a state after forming the molding. FIG. 2C shows a state before coating a mounting paste to a substrate.

As shown in FIGS. 2A and 2C, a plurality of resist materials 12 are formed within an area 14A where a semiconductor chip over a substrate 11 is mounted. These resist materials 12 are comprised of small pieces (projections) of an insulating material each having a predetermined size and arranged such that the interval between the resist materials 12 is set to be smaller than a predetermined distance.

Stated in more detail, these resist materials 12 are arranged at an interval (predetermined pitch) smaller than the predetermined distance in a horizontal row as shown in FIG. 2C. Further, any adjacent two rows (first and second rows) of the resist materials are so arranged that, at the center of a space between any one resist material 12 and the adjacent resist material 12 in one of the two rows, the center of the adjacent resist material 12 in the other row in a horizontal array is set. The projections 12 are comprised of a row/column array in which the projections in any horizontal row are arranged at a first pitch and the projections in any vertical column are arranged at a second pitch such that any one row of the projections is spaced apart, by one half the first pitch, from the adjacent row of the projections.

That is, these resist materials 12 are so arranged as to have a regular-spotted pattern in a row/column array.

A mounting paste 13 is coated on the resist material-formed substrate 11 and, by the mounting paste 13, the semiconductor chip 14 is bonded to the substrate 11. A respective bonding wire 15 is formed between a pad on the semiconductor chip 14 and a pad on the substrate 11 to make electrical connection therebetween.

After the bonding wire 15 has been formed, a molding 16 is formed in a later step to cover the semiconductor chip 14 and bonding wires 15 as shown in FIG. 2B. The molding 16 protects the semiconductor chip 14 and bonding wire 15 from a moisture and contaminant. The molding 16 is formed by an injection molding method by injecting a molten molding material and solidifying it.

In the injection molding, the molten molding material is injected, under a predetermined pressure, from above the semiconductor chip as indicated by arrows in FIG. 2A. In a resultant semiconductor device having a structure as shown in FIG. 2A, even if any air cavity is present beneath the semiconductor chip 14, since the projections of the resist material serve as a support, the resultant semiconductor chip 14 is prevented from being deformed, so that there is no possibility that bending stress will be applied to an extent that a crack occurs in the semiconductor chip 14. By doing so it is possible to prevent a crack in the semiconductor chip 14.

Further, the above-mentioned predetermined distance between the resist materials 12 can be found as shown below. The maximum bending stress of the semiconductor chip 14 becomes

σ_{Max}=3Wl²/(2bh²) (1)

Where W represents the injection pressure of the molding material; l, the length of the semiconductor chip over which a stress is applied; h, the thickness of the semiconductor chip; and σ_{Max}, b, values found by experiments.

From the equation (1), the length L of the semiconductor chip over which no crack occurs becomes

L=SQRT (2bh²/(3W·σ_{Max})) (2)

In this embodiment, for example, the thickness h of the semiconductor chip 14 is above 0.2 mm and the size of the semiconductor chip 14 is above 10 mm×13 mm. Further, the thickness of the substrate 11 is above 0.3 mm and the thickness of the resist material 12 is about 10 μm to 20 μm. Under such condition, the length L of the semiconductor chip in the equation (2) is 0.4 mm. Therefore, the above-mentioned predetermined distance between the resist materials 12 is 0.4 mm.

In this embodiment, it is necessary that the distance between the resist materials 12 be set to be below 0.4 mm.

In the semiconductor device having a structure as shown in FIG. 2A, even if a semiconductor chip is deformed when a molding material is injected at the injection molding process, the deformation of the semiconductor chip is suppressed because the resist materials as the projections serve as a support. Therefore, there is no possibility that any bending stress will be applied to an extent that a crack occurs.

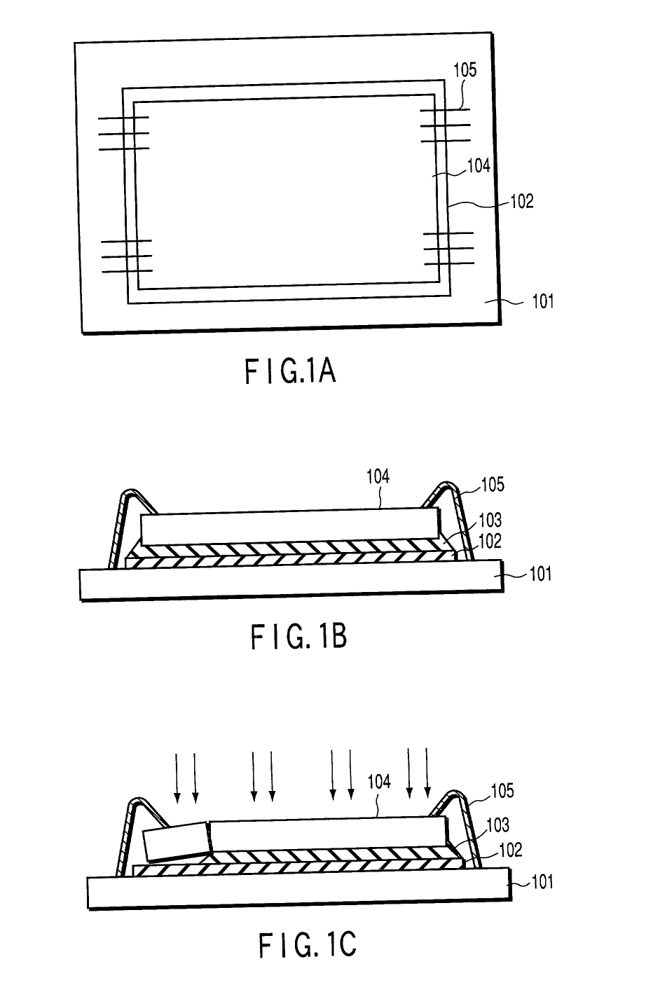

In the conventional semiconductor device as shown in FIGS. 1A, 1B and 1C, a push-down force with which the semiconductor chip on the mounting paste is pushed down toward the substrate is sometimes applied to an extent that, with a maximum force, the semiconductor chip is forced into contact with the substrate or resist material. In this case, the pushed-down mounting paste is inevitably pushed outside from between the semiconductor chip and the resist material. In the present embodiment, on the other hand, even in the case where such a maximum push-down force is applied, that is, to the extent that the semiconductor chip is forced into contact with the resist material, the mounting paste is pushed into a clearance between the resist materials spaced apart by the predetermined distance. It is, therefore, possible to easily control a pushed-out amount of mounting paste in comparison with the prior art case.

In the above-mentioned embodiment, even if a press-down force is applied to an extent that the semiconductor chip is forced into contact with the resist material, a bonding force can be secured between the semiconductor chip and the substrate by the mounting paste pushed into the clearance between the resist materials.

According to the present embodiment, as set out above, it is possible to control a formed state of the mounting paste formed between the semiconductor chip and the resist material and hence to reduce the occurrence of any crack in the semiconductor chip.

As set out above, according to the present invention, a semiconductor device can be provided which can control the formed state of the mounting paste formed beneath the semiconductor chip and reduce a possible occurrence of any crack in the semiconductor chip.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a plurality of projections each arranged on a substrate at an interval smaller than a predetermined distance and made of an insulating material;
a semiconductor chip positioned over the substrate on which these projections are formed; and
a mounting material formed between the substrate and the semiconductor chip to achieve a bond between the substrate and the semiconductor chip.

2. A semiconductor device according to claim 1, wherein plurality of projections are comprised of a row/column array wherein the projections in any horizontal row are arranged at a first pitch and the projections in any vertical column are arranged at a second pitch such that any one row of the projections is spaced apart, by one half the first pitch, from the adjacent row of the projections.

3. A semiconductor device according to claim 1, further comprising bonding wires formed between the substrate and the semiconductor chip; and
a molding formed on the semiconductor chip and bonding wires.

4. A semiconductor device according to claim 3, wherein the molding is formed by an injection molding method.

5. A semiconductor device comprising:
a plurality of projections each formed on a substrate at an interval smaller than a predetermined distance and made of an insulating material;
a semiconductor chip arranged on these projections; and
an insulating material formed between the substrate and the semiconductor chip and between projections on one hand and the semiconductor chip on the other hand achieving a bond therebetween.

6. A semiconductor device according to claim 5, further comprising
bonding wires formed between the substrate and the semiconductor chip; and
a molding formed on the semiconductor chip and bonding wires.

7. A semiconductor device according to claim 6, wherein the molding is formed by an injection molding method.

8. A semiconductor device comprising:
a plurality of projections each arranged on a substrate at an interval smaller than a predetermined distance and made of an insulating material;
a semiconductor chip arranged on these projections;
an insulating material formed between the substrate and the semiconductor chip and between projections on one hand and the semiconductor chip on the other hand achieving a bond therebetween;
bonding wires formed between the substrate and the semiconductor chip; and
a molding formed on the semiconductor chip and bonding wires.

9. A semiconductor device according to claim 8, wherein the molding is formed by an injection molding method.
